(19) United States
(12) Patent Application Publication
(10) Pub. No.: US 2004/0189341 A1
(43) Pub. Date: Sep. 30, 2004

(54) Power-on self test for a computer system

(76) Inventor: Kevin Liu, Irvine, CA (US)

Correspondence Address: PHILIP K. YU, 20955 PATHFINDER ROAD, SUITE 100, DIAMOND BAR, CA, 91765, US

(21) Appl. No.: 10/396,685

(22) Filed: Mar. 25, 2003

(51) Int. Cl. G06F 9/00; G06F 9/24; G06F 15/177; G06F 17/60; G06F 19/00; G01R 21/00; G01R 21/06; G06F 1/26; G06F 1/28; G06F 1/30; G01R 31/36

(52) U.S. Cl. 324/771; 713/300; 702/60

(57) ABSTRACT

A power-on self test (“POST”) apparatus and method for the power supply of PC, work station and server systems. A POST switch is installed in the power supply portion of the PC to allow the user to conduct self-testing of the power supply during troubleshooting. When the PC system becomes inoperative, activating the POST switch on the power supply will quickly determine whether the problem lies in the power supply or in the computer main board. The POST switch, when activated by the user, creates a power loop within the power supply by bringing a predetermined input terminal in the power supply to ground. If the power supply is operational, the cooling fan, and/or an LED indicator, will turn on, indicating its status. If the power supply is malfunctioning, the fan or the LED will not turn on, alerting the user that the power supply is where the failure lies. The input terminal in the power supply is a pin typically connected to receive a “POWER GOOD” signal from the PC, when the PC is turned on, so that the power supply can commence its operation. By switching that pin to its activated state using the POST switch, the power supply can be turned on, despite possible malfunctioning of the computer main board.

### FIELD OF THE INVENTION

The present application is related to power supplies and more particularly related to self testing of power supplies for personal computer, work station and server systems.

### BACKGROUND OF THE INVENTION

Personal computers have become as ubiquitous in our society as television sets and refrigerators. However, the operation of a PC is still much more complicated or delicate, in terms of the number of various components, as well as the software that operates the various components. When the PC does not function properly, it can be anyone's guess as to what the cause may be. It can be a hardware problem, or a software problem. Sometimes, even the user gets the blame for causing the PC to malfunction. As such, when performing diagnostics on a PC, it is imperative for the technician doing the tech support to systematically determine which part of the PC is acting up. If the troubleshooting is not done correctly, many hours of precious tech support time may be wasted. If the tech support is repairing a PC at the customer's site, its time becomes even more valuable.

During repair or troubleshooting of a PC, typically via telephone, one of the first questions that a tech support would ask of an already frustrated customer is that “Is the power cord connected?” or “Is the power switch turned on?” While such question may sound condescending to the customer, it is nevertheless an important part of the troubleshooting process. Even if the power is connected or the PC is switched on, the PC may still refuse to operate, if the power supply, which converts AC from the wall outlet to DC for the electronic components, fails. Even if the power supply is good, a malfunctioning motherboard will still cause the PC to be inoperable.

Conventionally, there is no convenient way to tell whether it is the power supply or other electronic components that have failed. In either situation, the PC will not operate. The inability to eliminate the power supply from the possible causes, for tech support purposes, has been quite frustrating to the PC industry.

Therefore, it would be desirable to be able to determine whether it is the power supply of a PC, a workstation or a server that fails, or something else. Such ability will allow a tech support to quickly move on with the troubleshooting of the other components. Such ability would allow the customers to help the tech support to quickly test the troubled PC.

### SUMMARY OF THE INVENTION

The present invention is directed to a power-on self test (“POST”) apparatus and method for the power supply of PC, work station and server systems. A POST switch is installed in the power supply portion of the PC to allow the user to conduct self-testing of the power supply during troubleshooting. When the PC system becomes inoperative, activating the POST switch on the power supply will quickly determine whether the problem lies in the power supply or in the computer main board. The POST switch, when activated by the user, creates a power loop within the power supply by bringing a predetermined input terminal in the power supply to ground. If the power supply is operational, the cooling fan, and/or an LED indicator, will turn on, indicating its status. If the power supply is malfunctioning, the fan or the LED will not turn on, alerting the user that the power supply is where the failure lies. The input terminal in the power supply is a pin typically connected to receive a “POWER GOOD” signal from the PC, when the PC is turned on, so that the power supply can commence its operation. By switching that pin to its activated state using the POST switch, the power supply can be turned on, despite possible malfunctioning of the computer main board.

### BRIEF DESCRIPTION OF THE PREFERRED EMBODIMENT

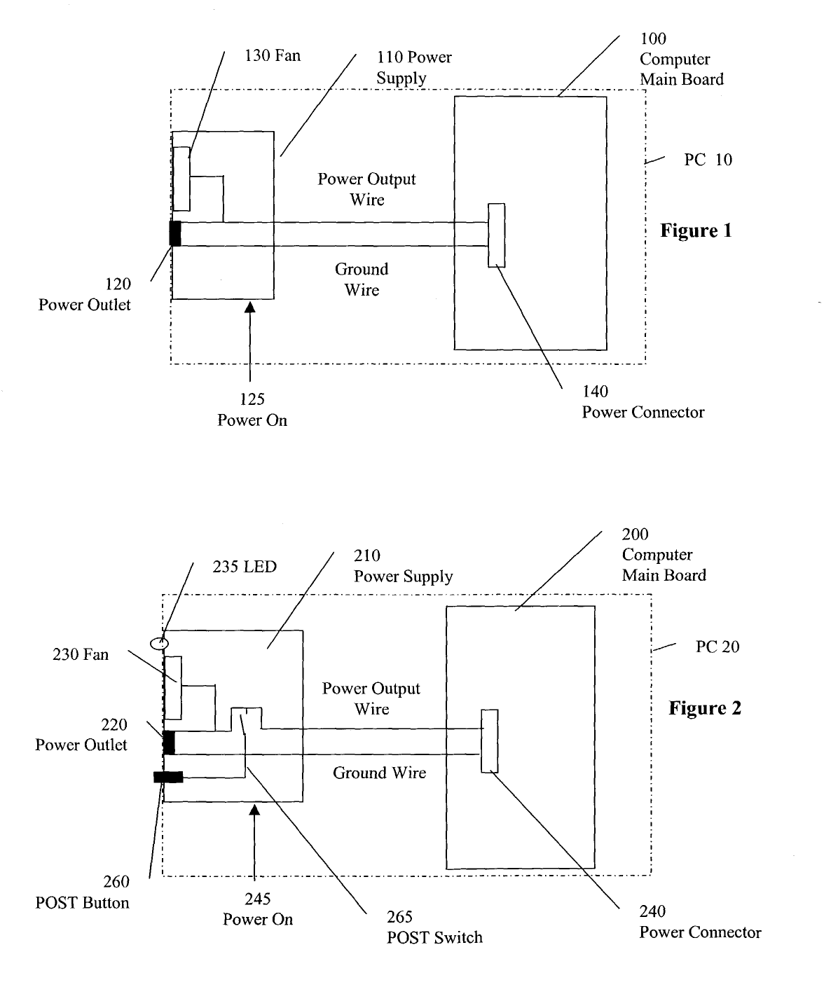

FIG. 1 is a simplified diagram illustrating a computer main board 100 and a power supply 110, as typically found in a PC or work station system.

FIG. 2 is a simplified diagram illustrating a computer main board 200 and a power supply 210 in accordance with the present invention.

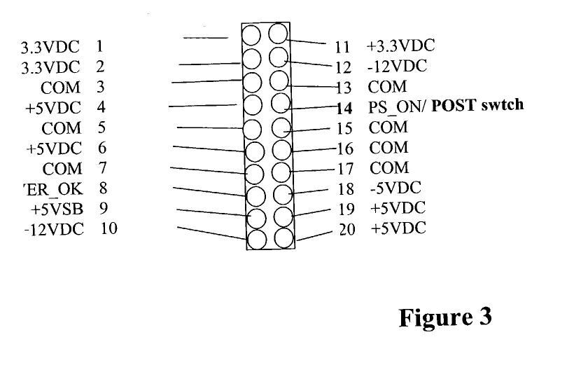

FIG. 3 is a simplified diagram illustrating the Main Power Connector for ATX and ATX12V power supply connectors.

### DETAILED DESCRIPTION OF THE PREFERRED EMBODIMENT

A system and method of doing power-on self test for a PC, work station or server is disclosed. In the description that follows, the present invention is described in terms of commonly known components and devices, which are the means generally used by those skilled in the art to communicate with each other. Based on the disclosure of the present application, those skilled in the art can readily practice the present invention.

FIG. 1 is a simplified diagram illustrating a computer main board 100 and a power supply 110, as can be found in a conventional PC or work station. The computer main board 100 represents a printed circuit board (“PCB”) with various electronic components of the PC 10. The power supply 110 is usually a separate system that converts electricity from a power outlet 120 to currents and voltages suitable for operating various devices on the main board 100 and on the PC 10 as a whole. A fan 130 is also an important part of the power supply 110, since it provides cooling to the components in the power supply 110, when the PC is turned on. The fan 130 will turn on when the PC 10 is turned on, since that is when the power supply 110 begins to convert. For a PC system, the design of a power supply has been well documented by a publication, entitled ATX/ATX12V: POWER SUPPLY DESIGN GUIDE, Version 1.2, published by a non-profit trade-group FormFactor.org. The ATX/ATX12V: POWER SUPPLY DESIGN GUIDE is hereby incorporated by reference as if full set forth herein.

When the power supply 110 is plugged in to the power outlet 120, it goes into a “STANDBY” mode, until the PC is turned on by the user. When the PC is eventually turned on, typically by the user's pressing of a power switch 125 on the PC, a “POWER GOOD” signal, or the “PS_ON# Signal” as specified by the ATX Main Power Connector of the Design Guide, is sent from the main board 100, as soon as the power switch on the PC 10 is turned on by the user, to the power supply 110. Upon receiving the “POWER GOOD” signal at its Pin No. 14, the power supply 110 will begin providing the converted currents and voltages to the main board 100, through a power connector 140 on the main board 100. However, if the main board 100 has a failure, it cannot generate the requisite “POWER GOOD” signal to turn the power supply 110 on. Without such a signal, the power supply 110, including the fan 130, will not operate, thus making the power supply 110 appear to be malfunctioning, when in fact it may not be.

Reference is to FIG. 2, where a simplified diagram illustrating a computer main board 200 and a power supply 210 in accordance with the present invention is shown. A power-on self test (“POST”) button 260 is implemented on the power supply 210 to control a POST switch 265. The POST switch 265, when the POST button 260 is activated by the user during troubleshooting of the PC 20, sends a signal to the aforementioned Pin No. 14, in place of the “POWER GOOD” signal. This way, the power supply 210 will turn on, since its state at Pin No. 14 has been brought to the same state when it receives the requisite “POWER GOOD” signal. The fan 230 will also turn on, thus providing an indication to the user that the power supply 210 is indeed functioning. The user can then target, or help the tech support on the telephone target, the troubleshooting efforts to the main board 200.

To implement the POST switch 265, it is preferable to install a POST button and a switch, where the switch 265 can force the power supply's Pin No. 14 to ground level (the same active state for Pin No. 14 upon reception of the “POWER GOOD” signal, in accordance with the Design Guide), when the POST button 260 is turned on. The rest of ATX Main Power Connection of the power supply 230 can remain unchanged, as illustrated in the pin-out diagram of FIG. 3.

The POST button 260 and POST switch 265 provide an efficient way for tech support and customers to quickly determine whether the PC's failure is from the power supply, or from the main board. The implementation of the POST button and POST switch creates a power loop within which the power supply's fan can operate, when the POST switch is activated. In addition to the fan 230, an LED indicator 235, which is also driven by the power supply 210, may be installed onto the external face of the power supply 210. When the POST button 260 is activated, the LED 235 will turn on if the power supply is good, thus providing a visual display of the status of the power supply.

What is claimed is:

1. A computer system, comprising:
a main board, having electronic components installed thereon for operating said computer system, said main board disposed to generate a first signal when it is turned on by a user;
a power supply coupled to said main board, said power supply disposed to convert supply voltages for use by said main board, upon receiving said first signal from said main board at a predetermined input terminal, said first signal disposed to bring said predetermined input terminal to a predetermined state;
a fan coupled to said power supply, said fan disposed to operate when said predetermined input terminal is brought to said predetermined state;
a self test switch coupled to said power supply, said self test switch disposed to transmit a second signal to said predetermined input terminal of said power supply, said second signal disposed to bring said predetermined input terminal to said predetermined state, such that said fan becomes operational if said power supply is functional.

2. The computer system of claim 1, further comprising:
a self-test activation button, said button disposed to activate said self test switch when operated by a user.

3. The computer system of claim 2, further comprising an LED, disposed to be operational when said predetermined input terminal is brought to said predetermined state.

4. The computer system of claim 2, wherein said first signal and said second signal are adapted to bring a voltage level at said predetermined input terminal to ground.

5. The computer system of claim 4, said power supply further comprising an LED, said LED disposed to become operational when said predetermined input terminal is brought to ground.

6. The computer system of claim 2, wherein said self-test activation button is disposed to activate said self-test switch when operated by a user through a telecommunication connection.

7. A power supply for a PC system, comprising:
a power converter, adapted to convert a first power level to a second power level for use by said PC system;
a control circuit coupled to said power converter, said control circuit disposed to controllably operate said power supply, upon receiving a POWER GOOD signal at a predetermined input terminal, said POWER GOOD signal capable of bringing said predetermined input terminal to a predetermined state;
a fan coupled to said control circuit, said fan disposed to become operational when said control circuit receives said POWER GOOD signal at said predetermined input terminal;
a self-test switch coupled to said control circuit and said fan, said switch disposed to transmit a second signal to said predetermined input terminal upon activation, said second signal capable of bringing said predetermined input terminal to said predetermined state, if said power supply is operating normally;
a self-test button coupled to said self-test switch, disposed to allow a user to activate said self-test switch.

8. The power supply of claim 7, further comprising:
an LED indicator coupled to said self-test switch and said control circuit, said LED indicator being disposed to turn on when said predetermined input terminal is brought to said predetermined state.

9. The power supply of claim 7, wherein said predetermined input terminal is Pin No. 14 and said predetermined state is ground.

10. The power supply of claim 8, wherein said predetermined input terminal is Pin No. 14 and said predetermined state is ground.

11. A method of troubleshooting a PC system, said PC system comprising a power supply and a main board, said power supply disposed to be turned on upon receiving, at a predetermined input terminal of said power supply, a first signal from said main board to bring said input terminal to a predetermined state, the method comprising:
a) supplying power to said power supply;
b) connecting a switch to said predetermined input terminal;
c) activating said switch to send a second signal to said predetermined input terminal, said second signal disposed to bring said predetermined input terminal to said state;
d) turning on a fan coupled to said power supply, if said second signal brings said predetermined input terminal to said predetermined state.

12. The method of claim 11, further comprising the step of e) turning on a LED indicator if said second signal brings said input terminal to said state.

13. The method of claim 11, wherein said predetermined input terminal is Pin No. 14 of said power supply.

14. The method of claim 12, wherein said predetermined input terminal is Pin No. 14 of said power supply.

15. The power supply of claim 8, wherein said predetermined input terminal is Pin No. 14 and said predetermined state is ground.

16. The computer system of claim 3, wherein said first signal and said second signal are adapted to bring a voltage level at said predetermined input terminal to ground.
